(19) United States
(12) Patent Application Publication
(10) Pub. No.: US 2026/0023135 A1
(43) Pub. Date: Jan. 22, 2026

(54) CONDUCTOR CORRECTION MODULE AND MEASUREMENT APPLICATION SYSTEM

(71) Applicant: Rohde & Schwarz GmbH & Co. KG, München (DE)

(72) Inventors: Johannes STEFFENS, Rosenheim (DE); Julius SEEGER, Prien am Chiemsee (DE)

(21) Appl. No.: 19/270,742

(22) Filed: Jul. 16, 2025

(30) Foreign Application Priority Data
Jul. 18, 2024 (EP) EP24189361.9
Nov. 15, 2024 (DE) DE102024133489.4

(51) Int. Cl. G01R 31/58

(52) U.S. Cl. CPC G01R 31/58

(57) ABSTRACT

The present disclosure shows a conductor correction module for continuous or discrete-time capture of properties of a conductor for electrical signal transmission, wherein the conductor correction module comprises a bidirectional optical interface couplable to at least one optical conductor of the conductor, an optical splitter comprising an input interface, a bidirectional test signal interface, and an output interface, and a property measurement unit coupled to the output interface of the optical splitter. The optical splitter is configured to receive an optical test signal and output a first part of the test signal via the bidirectional test signal interface and a second part of the test signal via the output interface. The optical splitter is further configured to output the received reflected optical signal via the output interface, wherein the property measurement unit determines at least one physical property of the conductor.

### TECHNICAL FIELD

The present disclosure relates to a conductor correction module and a corresponding measurement application system.

### TECHNICAL BACKGROUND

The present disclosure is described below primarily in connection with devices for measurement applications. It is understood that the disclosure is not limited to such devices and can be used in all systems or applications that include at least one of the following functions: capturing measurement values or signals, transmitting measurement values or signals, or generating measurement values or signals.

Particularly in the capture of measurement values in electronic systems where high signal frequencies are used, an exact determination of the properties of the measurement system is necessary. This applies to all components of the measurement system, such as the measurement application devices, but also to the transmission paths, i.e., for example, conductors.

### SUMMARY

An objective of the disclosure is therefore to enable accurate capture of the properties of conductors in measurement systems and other signal processing systems.

The objective is solved by the subject matter of the independent claims.

Disclosed is:

A conductor correction module for the continuous or discrete-time capture of properties of a conductor for electrical signal transmission, wherein the conductor correction module comprises: a bidirectional optical interface couplable to at least one optical conductor of the conductor; an optical splitter comprising an input interface, a bidirectional test signal interface, and an output interface; and a property measurement unit coupled to the output interface of the optical splitter. The bidirectional test signal interface of the optical splitter is coupled to the bidirectional optical interface, and the optical splitter is configured to receive an optical test signal via the input interface and to output a first part of the test signal via the bidirectional test signal interface, in particular to the bidirectional optical interface or directly to the bidirectional optical interface, and a second part of the test signal via the output interface. The bidirectional optical interface is configured to forward the received first part of the test signal into the optical conductor of the conductor, and to receive a reflected optical signal from the optical conductor and forward it to the bidirectional test signal interface. The optical splitter is further configured to output the received reflected optical signal via the output interface, in particular to the property measurement unit or directly to the property measurement unit, wherein the property measurement unit is configured to determine at least one physical property of the conductor based on the second part of the test signal and the received reflected optical signal.

Further disclosed is:

A measurement application system comprising: a conductor correction module according to one of the embodiments disclosed herein; a conductor comprising an electrical conductor and an optical conductor, wherein at least the optical conductor of the conductor is coupled to the conductor correction module; and a measurement application device coupled directly or indirectly via the conductor correction module to the electrical conductor of the conductor, wherein the measurement application device is configured to adapt a signal processing based on at least one physical property of the conductor determined by the conductor correction module.

The present disclosure is based on the insight that conductors in measurement applications can have a significant influence on the quality of signal measurement or signal generation. In particular, conductors in such applications can exhibit time-varying properties. For example, a change in ambient temperature, and thus conductor temperature, can lead to a change in the length of the conductor. Furthermore, the properties can also be changed by, for example, the position or bending of the conductor.

The present disclosure takes this insight into account and enables continuously monitoring or determining changing physical properties of a conductor. “Continuously” within the context of this disclosure can mean that the physical properties of a conductor are captured for the entire duration of use of the conductor correction module. This can occur continuously, i.e., without interruption, or cyclically at predetermined time intervals, e.g., several times per second, several times per minute, or several times per hour, or at other time intervals, i.e., discrete-time.

The physical properties of a conductor can be determined in particular without the use of external calibration aids. The physical properties of a conductor can thereby be determined during measurement operation, i.e., when the conductor is currently being used to measure a device under test.

Within the context of the present disclosure, the term “conductor” generally encompasses any type of electrical conductor capable of conducting electrical signals. Such conductors may comprise, for example, a wire or a strand or multiple wires or strands, which may, for example, be surrounded by a dielectric. Conductors can also be coaxial cables or conductors. Conductors according to the present disclosure can also include waveguides through which electrical waves can be transmitted.

It is understood that the present invention is not limited to measurement applications. Rather, it can also be used, for example, in other applications, such as radar applications or other RF applications.

For this purpose, the present disclosure provides the conductor correction module or the measurement application system with the conductor correction module and a corresponding measurement application device.

The conductor correction module comprises an optical splitter that receives an optical test signal via an input interface. The optical splitter splits the optical test signal and transmits a first part of the optical test signal via its bidirectional output interface to a bidirectional optical interface of the conductor correction module. A second part of the optical test signal is transmitted by the optical splitter via its output interface to a property measurement unit of the conductor correction module.

The bidirectional optical interface can be coupled externally to an optical conductor of the conductor to be tested or monitored.

The conductor correction module is configured to be used with conductors which serve for the transmission of electrical signals via an electrical signal path, and additionally comprise an optical signal path. Furthermore, such conductors comprise a corresponding reflector at the end of the optical signal path or optical conductor, which reflects a test signal fed in at the other end. Such conductors are described, for example, in EP 24 189 361.9, the content of which is hereby incorporated by reference in its entirety. Corresponding conductors can comprise, alongside an RF signal path, an optical signal path. The optical signal path serves for the parallel transmission of an optical signal which is not intended for data transmission or which does not serve the transmission of measurement signals or the measurement of a DUT. The optical signal rather serves for measuring properties of the conductor. The optical signal path can comprise a single optical fiber for the forward and return path. The optical signal path can, however, also comprise one optical fiber for the forward path and one optical fiber for the return path.

When the conductor correction module is connected to such a conductor or to the optical conductor of such a conductor, the first transmitted part of the optical test signal is reflected at the other end of the conductor and received in the bidirectional optical interface as a reflected optical signal.

The bidirectional optical interface forwards this reflected optical signal to the bidirectional test signal interface of the optical splitter. The optical splitter transmits the reflected optical signal via the output interface to the property measurement unit.

The property measurement unit determines at least one physical property of the conductor based on the second part of the optical test signal and the reflected optical signal.

The at least one physical property can be any possible property which can result from external influences on the conductor and which can be determined directly or indirectly by comparing the second part of the test signal with the reflected optical signal. An indirect determination is also understood to include determining a difference between the second part of the test signal and the reflected optical signal. In such an embodiment, the at least one physical property is only determined indirectly, e.g., as a phase difference or as an amplitude difference. For example, a change in length, a change in bend or radius, or a temperature change of the conductor can be determined directly or, for example, from the phase difference or the amplitude difference as the physical property.

Furthermore, further physical properties can be determined or calculated in the conductor correction module or a measurement application device of the measurement application system, e.g., a measurement device or a signal generation device, based on the data previously determined by the conductor correction module. Such properties can concern, for example, the above-mentioned indirectly determinable properties, or, for example, an impedance or impedance change of the conductor.

The conductor correction module can be coupled only to the optical conductor of the conductor, and transmit the determined physical properties to a corresponding measurement application device.

In embodiments, the conductor correction module can further comprise an electrical signal path or an RF signal path, which enables the transmission of electrical signals from a measurement application device to another element of the measurement application system. Such another element can be a further measurement application device or a so-called DUT (Device Under Test). The electrical signal path can comprise corresponding connectors or contacts which are electrically conductive or galvanically coupled.

The electrical signal path can be arranged, for example, together with the optical signal path in a common housing or connector. Such a housing can be configured, for example, to be coupled directly to a corresponding interface of a measurement application device. Such an interface can be, for example, a so-called “smart probe” or “active probe” interface that combines electrical signal transmission of the measurement application signal and digital data transmission.

In embodiments, the conductor correction module can comprise multiple parallel optical signal paths, optionally with corresponding electrical signal paths. Such a conductor correction module can be used to monitor multiple conductors simultaneously.

The measurement application system according to the present disclosure can comprise one or more conductor correction modules coupled to one or more corresponding conductors and measurement application devices.

A measurement application device according to the present disclosure can comprise any device used in a measurement application to capture an input signal or to generate an output signal, or that performs additional or supporting functions in a measurement application. A measurement application device can also be implemented as a program or software application executed as a measurement application on a computer or processor and capable of communicating with other measurement application devices to fulfill a measurement application task. A measurement application, also referred to as a measurement or test setup, can comprise, for example, at least one or several different measurement application devices used for electrical, magnetic, or electromagnetic measurements, particularly on individual devices under test, also called DUTs. A measurement application device according to the present disclosure can be configured to perform such electrical, magnetic, or electromagnetic measurements or signal generations, for example, in a measurement laboratory or in a production facility on the respective production line on a device under test. An exemplary measurement setup can serve to qualify the individual devices under test, i.e., to verify the proper electrical function of the respective devices under test.

For this purpose, measurement application devices can comprise at least one signal acquisition part for capturing electrical, magnetic, or electromagnetic signals from the device under test and/or at least one signal generation part for generating electrical, magnetic, or electromagnetic signals that can be supplied to the device under test. Such a signal acquisition part can comprise, for example but not limited to, a front-end stage for capturing, filtering, attenuating, or amplifying electrical signals. The signal generation part can comprise, for example but not limited to, corresponding signal generators, amplifiers, and filters. In embodiments, signal acquisition via the signal acquisition part occurs in a wired or contact-based manner. For this purpose, a corresponding measurement probe (also called a probe) can be connected to the measurement application device via a corresponding conductor. Likewise, in embodiments, signal generation and output via the signal generation part occurs in a wired or contact-based manner. For this, a corresponding signal output probe can be connected to the measurement application device via a corresponding conductor, or the signal is output directly via the conductor, e.g., to a device under test.

Furthermore, measurement application devices can comprise a signal processing unit during signal acquisition that processes the captured signals. The processing can include converting the captured signals from analog to digital signals and any other type of digital signal processing, for example converting time-domain signals to frequency-domain signals.

The measurement application devices can also comprise a user interface to display the captured signals to the user and to enable the user to control the measurement application devices. Of course, a housing can be provided that encloses the elements of the measurement application device. It is understood that additional elements such as a power supply circuit and communication interfaces can be provided.

A measurement application device can be a standalone device that can be operated in a measurement application without further elements to perform tests on a device under test. Naturally, communication capabilities can also be provided to connect the measurement application device to other measurement application devices.

A measurement application device can be, for example, a signal recording device such as an oscilloscope, particularly a digital oscilloscope, a spectrum analyzer, a signal analyzer, or a vector network analyzer. A measurement application device can also comprise a signal generation device, e.g., a signal generator, particularly a so-called “arbitrary signal generator”, also referred to as an “arbitrary waveform generator”, or a vector signal generator. Further possible measurement application devices include devices such as calibration standards or measurement probe tips.

Of course, at least some of the possible functions, such as signal recording and signal generation, can be combined in a single measurement application device.

In embodiments, the measurement application device can comprise pure data acquisition devices capable of capturing an input signal and transmitting the captured input signal as a digital input signal to a corresponding data storage or application server. Such pure data acquisition devices do not necessarily comprise a user interface or display. Instead, such pure data acquisition devices can be remotely controlled, e.g., via a corresponding data connection such as a network interface or a USB interface. The same applies to pure signal generation devices that can generate an output signal without having a user interface or configuration input devices. Instead, such signal generation devices can be operated remotely via a data connection.

Typically, measurement application systems are calibrated and subjected to so-called de-embedding before the start of operation, i.e., before the start of a measurement or signal generation. Through calibration and de-embedding, the properties of the signal paths in the measurement application system are captured and taken into account accordingly during operation.

Through the subject matter of the present disclosure, it is now possible to use time-variant correction terms instead of simple or static correction terms in the measurement application devices, into which the results of the determination of the physical properties flow. For example, the changing physical properties can be incorporated as an additional, variable parameter in the corresponding correction terms. In this process, conventional types of calibration or system error correction, such as a 1-port calibration, a 7-term calibration, or other methods, can continue to be used, as they merely need to be supplemented with an additional parameter whose value can change.

The measurement application devices can thereby correct signals accordingly, e.g., with respect to phase or time base.

With the conductor correction module and the measurement application system according to the present disclosure, it is possible to capture changing properties of conductors during operation of the measurement application system, so to speak in real time, and to take them into account accordingly in the measurement application devices.

Consequently, the accuracy of the measurement application system can be improved or kept stable over the operating duration.

Further embodiments and developments result from the dependent claims as well as from the description with reference to the figures. In particular, all embodiments mentioned herein can be combined in any order or number, unless individual features are mutually exclusive. In particular, the dependent claims of one claim category can also be developed according to another claim category. For example, the conductor correction module in the measurement application system can be configured according to each of the embodiments explicitly specified herein for the conductor correction module.

In an embodiment, which can be combined with all embodiments mentioned herein, the bidirectional test signal interface of the optical splitter can comprise a single signal port, in particular exactly one signal port, which is configured to emit the first part of the test signal and to receive the reflected optical signal.

This configuration enables the conductor correction module to be used with conductors that comprise only a single optical conductor which transmits the first part of the test signal and the reflected optical signal.

In yet another embodiment, which can be combined with all embodiments mentioned herein, the bidirectional test signal interface of the optical splitter can comprise a first signal port and a second signal port, wherein the first signal port is configured to emit the first part of the test signal, and the second signal port is configured to receive the reflected optical signal.

In such an embodiment, the first part of the test signal is transmitted via the first signal port to the conductor and the reflected optical signal is received via the second signal port.

This configuration enables the conductor correction module to be used with conductors that comprise two optical conductors, wherein one conductor transmits the first part of the test signal, and the other conductor transmits the reflected optical signal.

In yet a further embodiment, which can be combined with all embodiments mentioned herein, the output interface of the optical splitter can comprise a single signal port configured to output the second part of the test signal and to output the reflected optical signal.

In such an embodiment, the second part of the test signal is superimposed on the reflected optical signal and the superimposed signals are transmitted to the property measurement unit.

In an embodiment, which can be combined with all embodiments mentioned herein, the output interface of the optical splitter can comprise a first signal port and a second signal port, wherein the first signal port is configured to output the second part of the test signal, and the second signal port is configured to output the reflected optical signal.

In such an embodiment, the second part of the test signal is transmitted via the first signal port to the property measurement unit and the reflected optical signal is transmitted via the second signal port to the property measurement unit.

The superimposed transmission and the separate transmission of the second part of the test signal and the reflected optical signal can each enable different evaluations.

In yet another embodiment, which can be combined with all embodiments mentioned herein, the property measurement unit can comprise a digital data interface and be configured to output the determined physical properties via the digital data interface.

As already explained above, the property measurement unit can determine the physical properties directly or indirectly. The property measurement unit can consequently determine values that directly characterize the physical properties or from which the magnitudes of the physical properties can be calculated.

The digital data interface enables the transmission of the determined data on the physical properties to, e.g., a measurement application device, which can use this data for the correction of measurement values. If the physical properties are determined indirectly, the measurement application device can determine the corresponding values based on the transmitted data.

The digital data interface can also be used for the transmission of electrical energy to supply the property measurement unit or other components of the conductor correction module. Alternatively, a corresponding energy transmission interface can be provided. Such an energy transmission interface can be combined with the data interface, as is customary, for example, with USB interfaces.

Further possible types of digital data interface can comprise, for example, any type of wired and wireless communication interfaces, such as a network interface, in particular an Ethernet, WLAN, or WiFi interface, a USB interface, a Bluetooth interface, an NFC interface, a visible or invisible light-based interface, in particular an infrared interface.

In yet a further embodiment, which can be combined with all embodiments mentioned herein, the property measurement unit can be configured to perform at least one of the following functions: determine a phase difference between the second part of the test signal and the reflected optical signal, determine a time difference between the second part of the test signal and the reflected optical signal, determine correlation information between the second part of the test signal and the reflected optical signal, and determine amplitude information for the second part of the test signal and the reflected optical signal.

The phase difference can be used, for example, for a periodic optical test signal to determine, e.g., propagation time changes in the conductor.

A time difference can be used, for example, in the analysis of pulsed or non-periodic signals to determine a propagation time change in the conductor.

The correlation information can be calculated, for example, when the temporal offset between the second part of the test signal and the reflected signal becomes too large. Within the context of the present disclosure, the term “correlation information” particularly means the correlation coefficient between the two signals. This can be determined, for example, sectionally over specific time intervals. A time interval can be the sampling time of the measurement application device.

Amplitude information, also called amplitude, can be determined to determine the attenuation of the conductor.

It is understood that the property measurement unit can determine individual or any combination of these parameters, i.e., e.g., phase difference and time difference, phase difference and correlation information, phase difference and amplitude information, time difference and correlation information, time difference and amplitude information, correlation information and amplitude information, phase difference and time difference and correlation information, phase difference and time difference and amplitude information, and time difference and correlation information and amplitude information.

The determined quantities or data can be transmitted, e.g., via the aforementioned digital data interface to a measurement application device. It is understood that the properties of the optical conductor are determined, and from these, the properties of the electrical conductor are inferred. For example, the measurement application device can determine the changes in the physical property of the conductor from the determined quantities. In further embodiments, the property measurement unit itself can determine the changes in the physical property of the conductor from the determined quantities and transmit them to the measurement application device. For this purpose, a corresponding computing unit can be provided, e.g., in the property measurement unit.

In yet another embodiment, which can be combined with all embodiments mentioned herein, the property measurement unit can comprise at least one photodetector and at least one analog-to-digital converter coupled to the at least one photodetector.

With a combination of photodetector and analog-to-digital converter, also called ADC, optical signals can be processed reliably and with few components. Furthermore, the digital output signals of the ADCs can be easily forwarded or further processed.

Exactly one ADC can be provided for each of the photodetectors. Alternatively, one ADC can be coupled to multiple photodetectors and capture a superimposed signal.

Multiple photodetectors can also be collectively configured as a so-called “balanced photodetector”.

In an embodiment, which can be combined with all embodiments mentioned herein, the property measurement unit can comprise: a first photodetector configured to capture the second part of the optical test signal and output a first electrical signal; a second photodetector configured to capture the reflected optical signal and output a second electrical signal; a combiner coupled to the first photodetector and the second photodetector, and configured to combine the first electrical signal with the second electrical signal; and an analog-to-digital converter coupled to the combiner and configured to convert the combined electrical signal into a digital signal and output it.

In such a configuration, a combiner for two analog electrical signals is used to combine the two output signals of the photodetectors and transmit them to a single analog-to-digital converter.

In each of the exemplary embodiments cited herein, e.g., a photodiode can serve as a photodetector. When two photodetectors are used, a so-called balanced photodetector can also be employed.

The electrical combiner can serve, for example, to determine a phase difference from the two electrical signals. Such a combiner can comprise, e.g., an analog phase detector, an analog mixer, a digital phase detector/mixer, or a lock-in amplifier.

In yet another embodiment, which can be combined with all embodiments mentioned herein, the property measurement unit can comprise: an optical combiner configured to combine the second part of the optical test signal with the reflected optical signal; a photodetector coupled to the optical combiner and configured to capture the combined optical signal and output a corresponding electrical signal; and an analog-to-digital converter coupled to the photodetector and configured to convert the electrical signal into a digital signal and output it.

In such a configuration, an optical combiner is used, and only a combined optical signal is fed to a single photodetector. Such an embodiment can be used particularly with a phase- or frequency-modulated test signal.

As an optical combiner, also called an optical coupler, e.g., a fiber-based power splitter, e.g., a fiber-based power splitter manufactured by splicing, can be used. Optical couplers can be realized via fibers or, as in electronics, in a semiconductor substrate, for example silicon on insulator (SOI). Superposition in free space via mirrors and beamsplitter or PBS (polarizing beam splitter) is also possible.

In yet a further embodiment, which can be combined with all embodiments mentioned herein, the optical splitter can be configured to output the second part of the optical test signal and the reflected optical signal as a combined optical signal to the property measurement unit, wherein the property measurement unit can comprise: a photodetector configured to capture the combined optical signal and output a corresponding electrical signal; and an analog-to-digital converter coupled to the photodetector and configured to convert the electrical signal into a digital signal and output it.

In such embodiments, the second part of the optical test signal and the reflected optical signal can already be combined in the optical splitter and supplied to the property measurement unit as a combined optical signal.

In yet another embodiment, which can be combined with all embodiments mentioned herein, the property measurement unit can comprise: a first photodetector configured to capture the second part of the optical test signal and output a first electrical signal; a second photodetector configured to capture the reflected optical signal and output a second electrical signal; a first analog-to-digital converter coupled to the first photodetector and configured to convert the first electrical signal into a first digital signal; a second analog-to-digital converter coupled to the second photodetector and configured to convert the second electrical signal into a second digital signal; and a combiner coupled to the first analog-to-digital converter and the second analog-to-digital converter, and configured to combine the first digital signal with the second digital signal and output it.

The combining of the first digital signal with the second digital signal can here be understood as the actual measurement process through which the signal to be captured and output by the measurement is generated. In particular, a phase difference or an amplitude difference can be determined through the combining. This explanation applies analogously to the combiners already disclosed above, which can be, for example, digital or optical combiners.

In such a configuration, the second part of the optical test signal and the reflected optical signal are routed separately until they are present as digital data. A digital combiner can then combine the two digital datasets or streams into one digital signal. Such a combiner can be implemented, for example, as an algorithm in a DSP or ASIC.

In yet a further embodiment, which can be combined with all embodiments mentioned herein, the conductor correction module can further comprise an optical signal source coupled to the input interface of the optical splitter and configured to generate the optical test signal and transmit it to the optical splitter.

In such embodiments, the conductor correction module can itself comprise an optical signal source which generates the optical test signal and transmits it to the optical splitter. Thereby, the conductor correction module can be provided as a self-contained unit requiring no further external components. The optical signal source can be, for example, a modulatable laser source. Particularly at low frequencies, direct modulation of the laser diode can be used. At higher frequencies, this is not always possible. In such applications, an electro-absorptive modulator or Mach-Zehnder modulator can be combined with a CW laser.

In an embodiment, which can be combined with all embodiments mentioned herein, the conductor correction module can further comprise an optical input interface coupled to the input interface of the optical splitter and configured to receive the optical test signal and transmit it to the optical splitter.

In such embodiments, the conductor correction module can be configured without its own optical signal source. Thereby, the conductor correction module can be flexibly coupled with external optical signal sources.

In embodiments, the conductor correction module can also combine an internal optical signal source with an interface for an external optical signal source.

In embodiments, multiple of the above-mentioned architectures can also be arranged in the conductor correction module. Furthermore, a switch can be provided, for example, with which switching between the individual architectures can be performed. Such a switch can be controlled manually by a user or via the digital data interface.

In yet another embodiment, which can be combined with all embodiments mentioned herein, the optical test signal can comprise at least one signal from the following optical signals: a periodically modulated signal, an amplitude-modulated signal, a phase-modulated signal, a frequency-modulated signal, a chirp-modulated signal, and a pulse-modulated signal.

The optical test signal can be flexibly chosen to optimally support the respective application. Depending on the physical parameters to be determined, a suitable modulation type can consequently be selected.

In an embodiment, which can be combined with all embodiments mentioned herein, the property measurement unit can be configured to determine a change in an absolute length of the conductor based on the second part of the test signal and the received reflected optical signal.

The property measurement unit can comprise, for example, a processor or configurable logic component, e.g., a CPLD, or FPGA, or an ASIC, which can determine the absolute length change of the conductor.

In particular, the property measurement unit can metrologically determine the absolute length of the conductor at the start of operation and subsequently continuously determine the length change of the conductor.

With such a conductor correction module, the absolute length difference between multiple conductors connected, for example, to measurement devices/radio direction finders/etc. can be determined, and their temporal change can be determined in real time. This is particularly necessary when, for example, in direction finding with multiple antennas, the absolute propagation times and phases of multiple conductors used and their change must be monitored.

The term “absolute length” also implies that, for example, a conductor break in the conductor can be detected by comparing the captured length with a known target length of the conductor. If the captured length deviates from the target length by more than a predetermined threshold value, a conductor break can be detected.

In yet another embodiment, which can be combined with all embodiments mentioned herein, the conductor correction module can further comprise a memory configured to store the length of the conductor in a reference state.

The term reference state refers to a state of the conductor in which the conductor has a defined length. This state can exist, for example, at the end of production of the conductor. The length of the conductor can be determined, for example, in a so-called end-of-line test.

The determination of a length change can subsequently be performed during operation by the property measurement unit. Merely determining the change in length requires less complex operations than determining the absolute length.

In the memory, besides the absolute length of the conductor, further information, such as a type of the conductor or an identifier of the conductor, can be stored.

The conductor correction module can further comprise an identification interface, e.g., an RFID interface, via which the conductor can be identified to read the corresponding data from the memory.

Alternatively, the absolute length of the conductor can also be read out via this interface from a data storage in the conductor. In further embodiments, the absolute length can also be communicated to the property measurement unit via the digital data interface. For example, a measurement application device can retrieve this information, knowing a serial number of the conductor, from a corresponding server.

In an embodiment, which can be combined with all embodiments mentioned herein, the conductor correction module can further comprise a timing unit coupled to the property measurement unit and configured to output a timing signal, wherein the property measurement unit can be configured to determine an absolute propagation time of the first part of the optical test signal in the conductor based on the timing signal.

The timing unit can alternatively also be installed in the measurement application device. The timing unit can also be arranged as a dedicated unit in the measurement application system. The timing signal can be transmitted from the measurement application device or the dedicated unit to the conductor correction module via a corresponding interface.

The timing unit can comprise a corresponding timing component, e.g., an oscillator. Further possible embodiments of the timing unit can comprise, e.g., a GPS receiver that receives a GPS signal, or other radio receivers.

If the absolute propagation time of the first part of the optical test signal in the conductor is determined, the absolute length of the conductor can be determined directly. It is thus not necessary to communicate the absolute length to the conductor correction module or to store it in a memory.

In yet another embodiment of the measurement application system, which can be combined with all embodiments mentioned herein, the conductor correction module can be arranged in the measurement application device. Alternatively, the conductor correction module can be arranged externally to the measurement application device and the conductor, between the measurement application device and the conductor. Furthermore, the conductor correction module can be arranged in the conductor.

### BRIEF DESCRIPTION OF THE DRAWINGS

The present disclosure is explained in more detail below with reference to the exemplary embodiments indicated in the schematic figures of the drawings.

FIG. 1 shows a block diagram of a possible embodiment of a conductor correction module according to the present disclosure;

FIG. 2 shows a block diagram of another possible embodiment of a conductor correction module according to the present disclosure;

FIG. 3 shows a block diagram of another possible embodiment of a conductor correction module according to the present disclosure;

FIG. 4 shows a block diagram of another possible embodiment of a conductor correction module according to the present disclosure;

FIG. 5 shows a block diagram of another possible embodiment of a conductor correction module according to the present disclosure;

FIG. 6 shows a block diagram of a possible embodiment of a property measurement unit according to the present disclosure;

FIG. 7 shows a block diagram of another possible embodiment of a property measurement unit according to the present disclosure;

FIG. 8 shows a block diagram of another possible embodiment of a property measurement unit according to the present disclosure;

FIG. 9 shows a block diagram of another possible embodiment of a property measurement unit according to the present disclosure;

FIG. 10 shows a block diagram of another possible embodiment of a conductor correction module according to the present disclosure;

FIG. 11 shows a block diagram of another possible embodiment of a conductor correction module according to the present disclosure;

FIG. 12 shows a block diagram of another possible embodiment of a conductor correction module according to the present disclosure; and

FIG. 13 shows a block diagram of a possible embodiment of a measurement application system according to the present disclosure.

In all figures, identical or functionally equivalent elements and devices—unless otherwise specified—are provided with the same reference numerals.

### DETAILED DESCRIPTION OF THE DRAWINGS

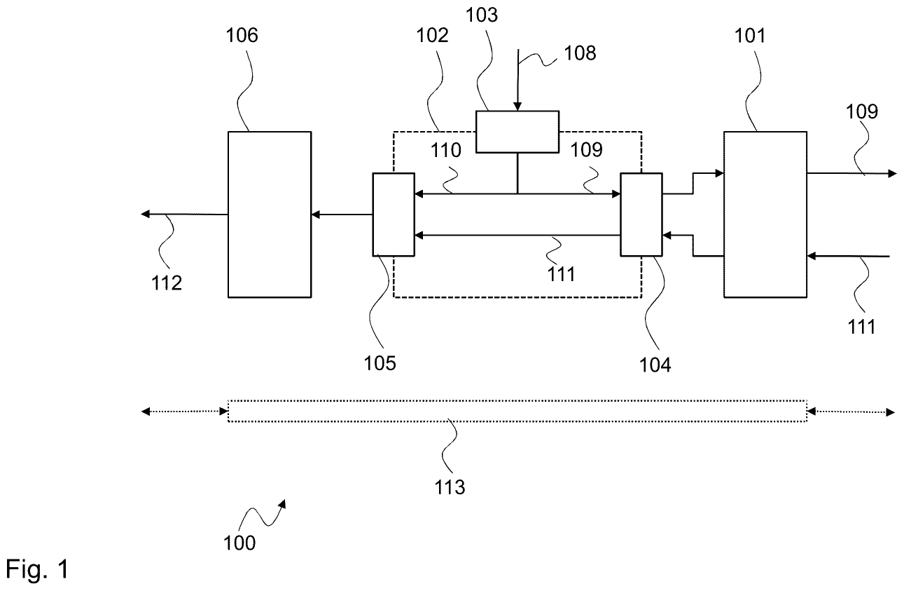

FIG. 1 shows a conductor correction module 100. The conductor correction module 100 comprises: a bidirectional optical interface 101, an optical splitter 102, and a property measurement unit 106. The optical splitter 102 comprises an input interface 103, a bidirectional test signal interface 104, and an output interface 105. The bidirectional optical interface 101 can be coupled to at least one optical conductor of a conductor. The bidirectional test signal interface 104 of the optical splitter 102 is coupled to the bidirectional optical interface 101; the output interface 105 of the optical splitter 102 is coupled to the property measurement unit 106.

The optical splitter 102 receives an optical test signal 108 via the input interface 103 and outputs a first part 109 of the test signal 108 via the bidirectional test signal interface 104. Simultaneously, the optical splitter 102 outputs a second part 110 of the test signal 108 via the output interface 105 to the property measurement unit 106. The first part 109 and the second part 110 each represent signal portions, in particular identical or amplitude-varied identical signal portions, of the test signal 108, which can be generated, for example, by means of an optical splitter, e.g., a semi-transparent mirror.

The bidirectional optical interface 101 transmits the first part 109 of the test signal 108 into the optical conductor and receives a reflected optical signal 111 from the optical conductor. The bidirectional optical interface 101 forwards the received reflected optical signal 111 back to the bidirectional test signal interface 104. The optical splitter 102 also forwards the received reflected optical signal 111 via the output interface 105 to the property measurement unit 106.

The property measurement unit 106 determines at least one physical property 112 of the conductor based on the second part 110 of the test signal 108 and the received reflected optical signal 111. The determined at least one physical property 112 can subsequently be forwarded to, e.g., a corresponding measurement application device.

The conductor correction module 100 further comprises an optional RF signal path 113 through which an RF signal can be conducted from a source into an RF conductor of the conductor or vice versa.

It is understood that all elements of the conductor correction module 100 can be arranged in a common housing, and corresponding connectors can be provided to contact the conductor correction module 100.

It is understood that the explanations regarding other embodiments of the conductor correction module described herein apply mutatis mutandis to the conductor correction module 100.

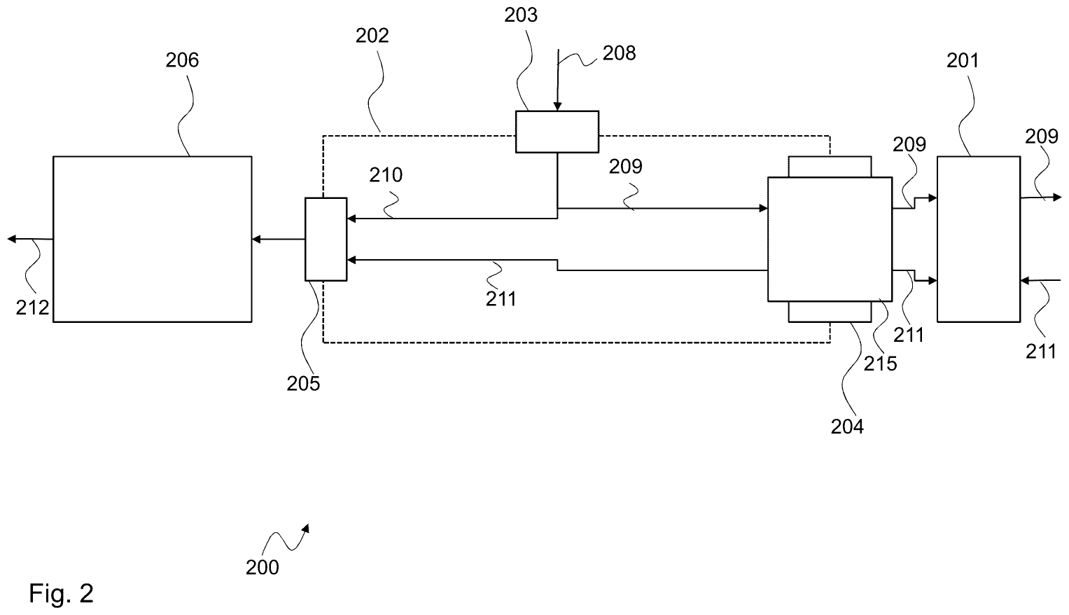

FIG. 2 shows a conductor correction module 200. The conductor correction module 200 is based on the conductor correction module 100. Consequently, the conductor correction module 200 comprises: a bidirectional optical interface 201, an optical splitter 202, and a property measurement unit 206. The optical splitter 202 comprises an input interface 203, a bidirectional test signal interface 204, and an output interface 205. The bidirectional optical interface 201 can be coupled to at least one optical conductor of a conductor. The bidirectional test signal interface 204 of the optical splitter 202 is coupled to the bidirectional optical interface 201; the output interface 205 of the optical splitter 202 is coupled to the property measurement unit 206. It is understood that the explanations regarding other embodiments of the conductor correction module described herein apply mutatis mutandis to the conductor correction module 200.

In the conductor correction module 200, the bidirectional test signal interface 204 of the optical splitter 202 comprises a single signal port 215. This can emit the first part 209 of the test signal 208 and also receive the reflected optical signal 211.

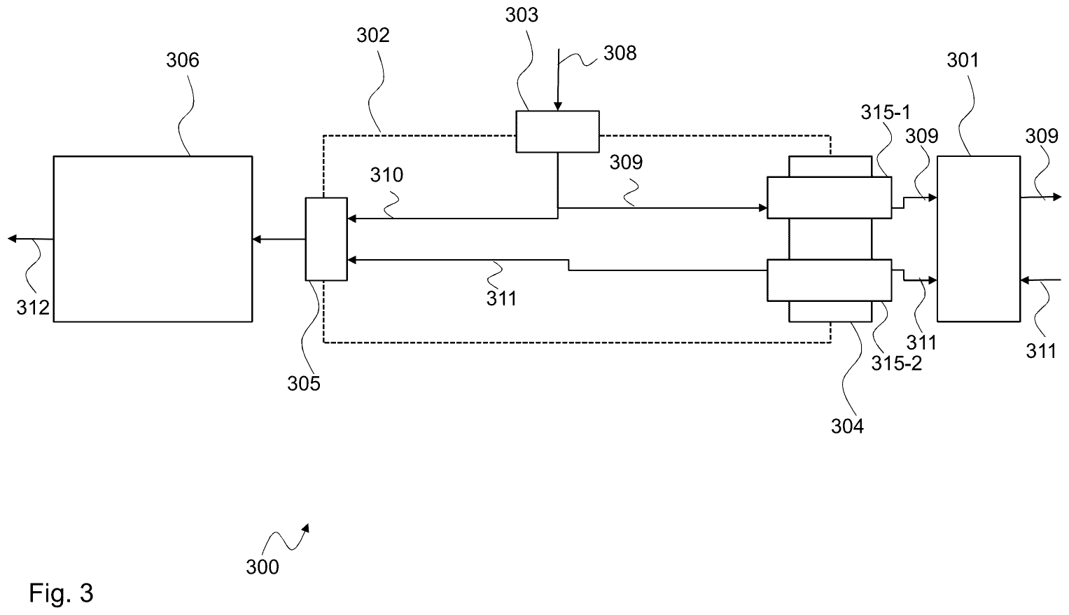

FIG. 3 shows a conductor correction module 300. The conductor correction module 300 is based on the conductor correction module 100. Consequently, the conductor correction module 300 comprises: a bidirectional optical interface 301, an optical splitter 302, and a property measurement unit 306. The optical splitter 302 comprises an input interface 303, a bidirectional test signal interface 304, and an output interface 305. The bidirectional optical interface 301 can be coupled to at least one optical conductor of a conductor. The bidirectional test signal interface 304 of the optical splitter 302 is coupled to the bidirectional optical interface 301; the output interface 305 of the optical splitter 302 is coupled to the property measurement unit 306. It is understood that the explanations regarding other embodiments of the conductor correction module described herein apply mutatis mutandis to the conductor correction module 300.

The bidirectional test signal interface 304 of the optical splitter 302 comprises a first signal port 315-1 and a second signal port 315-2. The first signal port 315-1 is configured to emit the first part 309 of the test signal 308, and the second signal port 315-2 is configured to receive the reflected optical signal 311.

The first signal port 315-1 and the second signal port 315-2 can particularly be used with conductors comprising two optical fibers, as explained above.

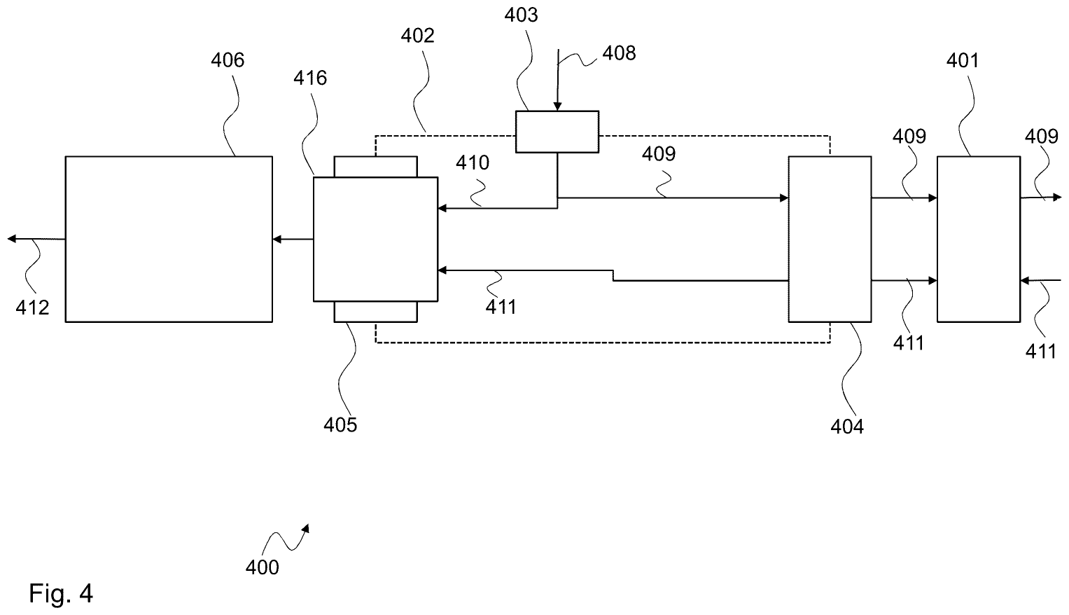

FIG. 4 shows a conductor correction module 400. The conductor correction module 400 is based on the conductor correction module 100. Consequently, the conductor correction module 400 comprises: a bidirectional optical interface 401, an optical splitter 402, and a property measurement unit 406. The optical splitter 402 comprises an input interface 403, a bidirectional test signal interface 404, and an output interface 405. The bidirectional optical interface 401 can be coupled to at least one optical conductor of a conductor. The bidirectional test signal interface 404 of the optical splitter 402 is coupled to the bidirectional optical interface 401; the output interface 405 of the optical splitter 402 is coupled to the property measurement unit 406. It is understood that the explanations regarding other embodiments of the conductor correction module described herein apply mutatis mutandis to the conductor correction module 400.

The output interface 405 of the optical splitter 402 comprises a single signal port 416 that outputs the second part 410 of the test signal 408 and the reflected optical signal 411.

Although not separately shown, the signal port 416, or the optical splitter 402, can comprise a corresponding optical mixer to mix the second part 410 of the test signal 408 and the reflected optical signal 411 and output it via the single signal port 416.

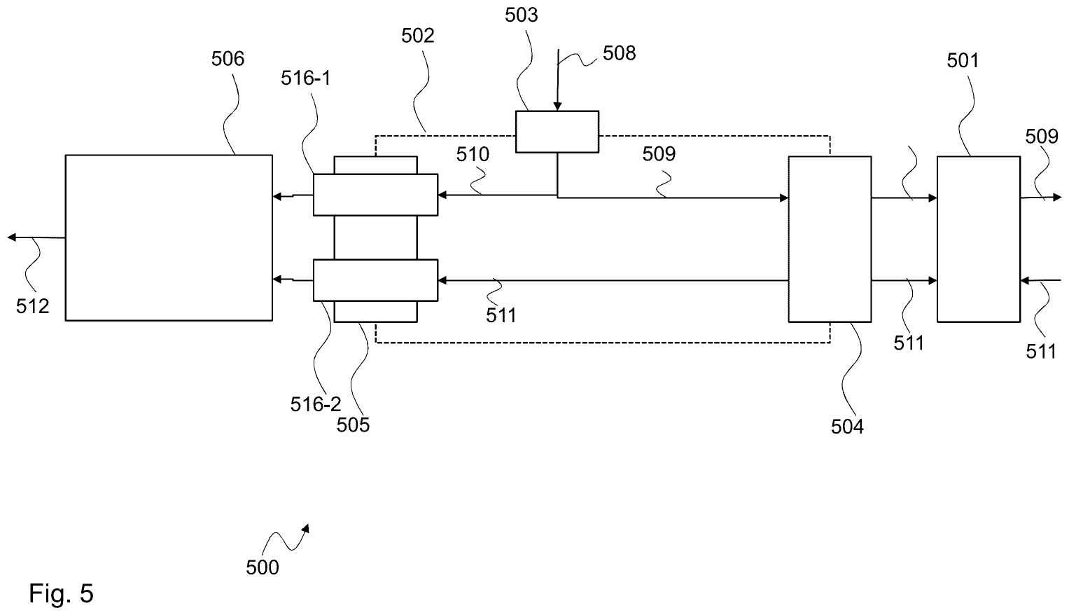

FIG. 5 shows a conductor correction module 500. The conductor correction module 500 is based on the conductor correction module 100. Consequently, the conductor correction module 500 comprises: a bidirectional optical interface 501, an optical splitter 502, and a property measurement unit 506. The optical splitter 502 comprises an input interface 503, a bidirectional test signal interface 504, and an output interface 505. The bidirectional optical interface 501 can be coupled to at least one optical conductor of a conductor. The bidirectional test signal interface 504 of the optical splitter 502 is coupled to the bidirectional optical interface 501; the output interface 505 of the optical splitter 502 is coupled to the property measurement unit 506. It is understood that the explanations regarding other embodiments of the conductor correction module described herein apply mutatis mutandis to the conductor correction module 500.

The output interface 505 of the optical splitter 502 comprises a first signal port 516-1 and a second signal port 516-2. The first signal port 516-1 outputs the second part 510 of the test signal 508, and the second signal port 516-2 outputs the reflected optical signal 511.

The property measurement unit 506 consequently receives two separate signals for further processing.

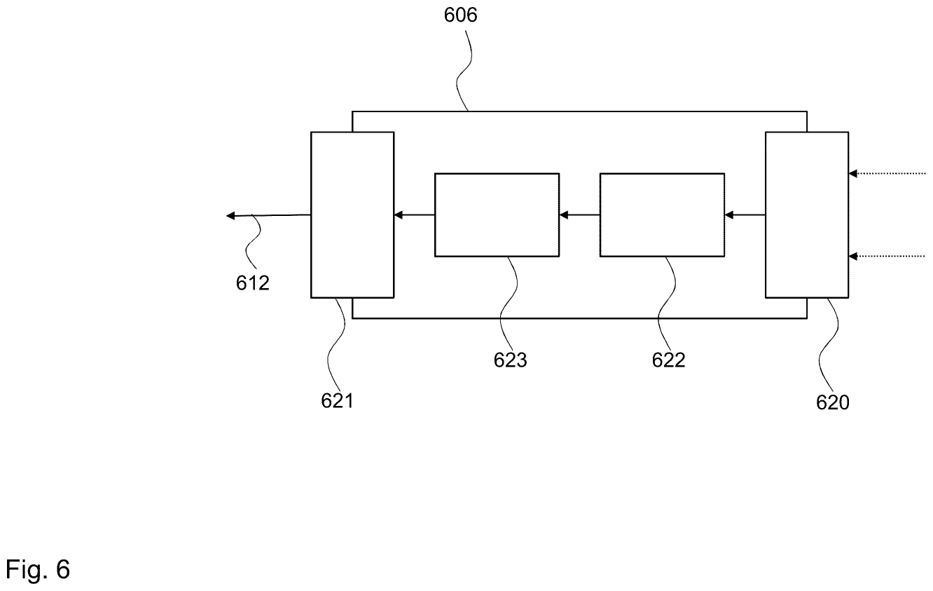

FIG. 6 shows a property measurement unit 606. The property measurement unit 606 comprises an input interface 620 coupled to at least one photodetector 622, which is coupled to at least one analog-to-digital converter 623. The at least one analog-to-digital converter 623 is coupled to a digital data interface 621.

The input interface 620 receives the second part of the test signal and the reflected optical signal and forwards them to the photodetector 622, which generates electrical signals from the two optical signals and forwards them to the analog-to-digital converter 623. The analog-to-digital converter 623 outputs a corresponding digital signal via the data interface 621, which comprises the at least one physical property 612.

It is understood that the explanations regarding other embodiments of the property measurement unit described herein apply mutatis mutandis to the property measurement unit 606.

In the shown embodiment, the optical splitter can, for example, output the second part of the optical test signal and the reflected optical signal as a combined optical signal to the property measurement unit.

The property measurement unit 606 can, for example, determine a phase difference between the second part of the test signal and the reflected optical signal, or determine a time difference between the second part of the test signal and the reflected optical signal, or determine correlation information between the second part of the test signal and the reflected optical signal, or determine amplitude information for the second part of the test signal and the reflected optical signal. The property measurement unit 606 can further determine a change in an absolute length of the conductor based on the second part of the test signal and the received reflected optical signal.

It is understood that every embodiment of the property measurement unit described herein can be employed in any embodiment of the conductor correction module.

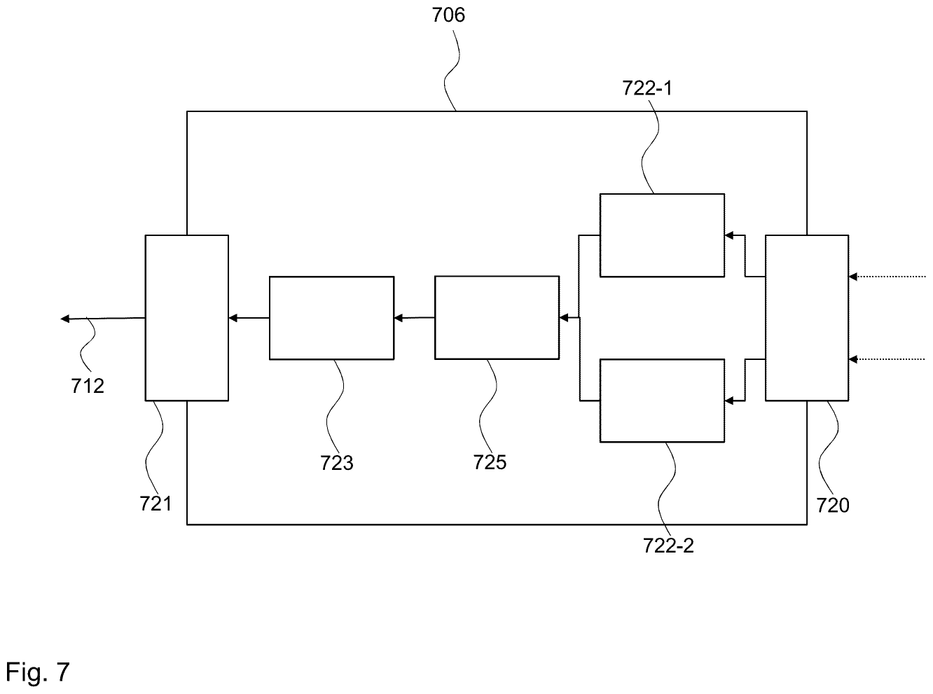

FIG. 7 shows a property measurement unit 706. It is understood that the explanations regarding other embodiments of the property measurement unit described herein apply mutatis mutandis to the property measurement unit 706.

The property measurement unit 706 receives the second part of the test signal and the reflected optical signal and is coupled to a first photodetector 722-1 and a second photodetector 722-2.

The first photodetector 722-1 captures the second part of the optical test signal and outputs a first electrical signal. The second photodetector 722-2 captures the reflected optical signal and outputs a second electrical signal.

The two electrical signals are combined by a combiner 725 into a single electrical signal and fed to an analog-to-digital converter 723, which converts the combined electrical signal into a digital signal and outputs it as the physical property 712 via the data interface 721.

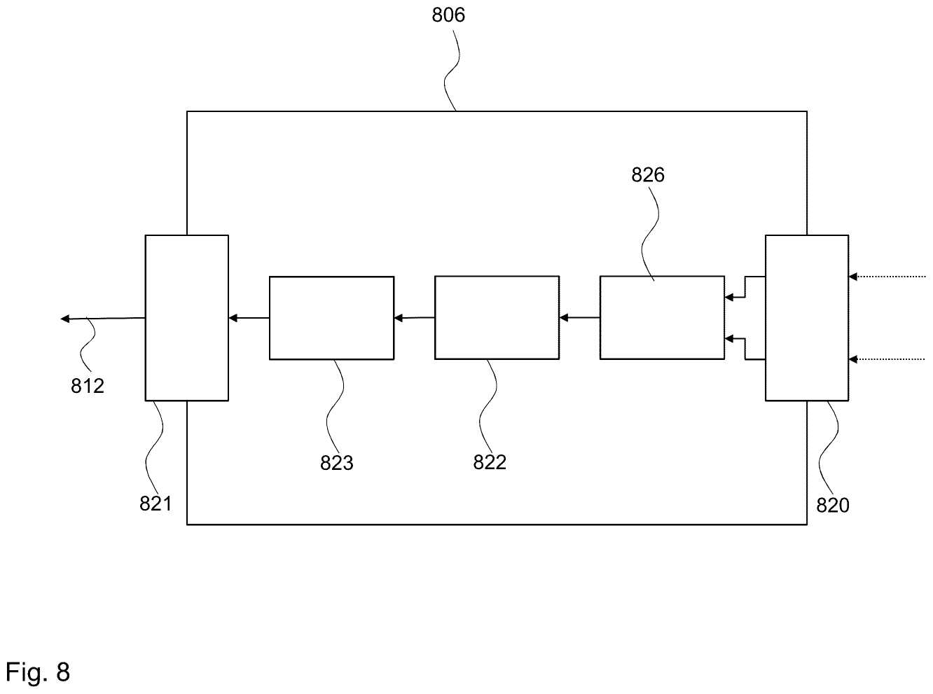

FIG. 8 shows a property measurement unit 806. It is understood that the explanations regarding other embodiments of the property measurement unit described herein apply mutatis mutandis to the property measurement unit 806.

The property measurement unit 806 comprises an input interface 820 which receives the second part of the test signal and the reflected optical signal. Furthermore, the property measurement unit 806 is coupled to an optical combiner 826 that combines the second part of the optical test signal with the reflected optical signal. The optical combiner 826 is coupled to the photodetector 822, which captures the combined optical signal and outputs a corresponding electrical signal. Analog-to-digital converter 823 converts the electrical signal into a digital signal and outputs it as the physical property 812.

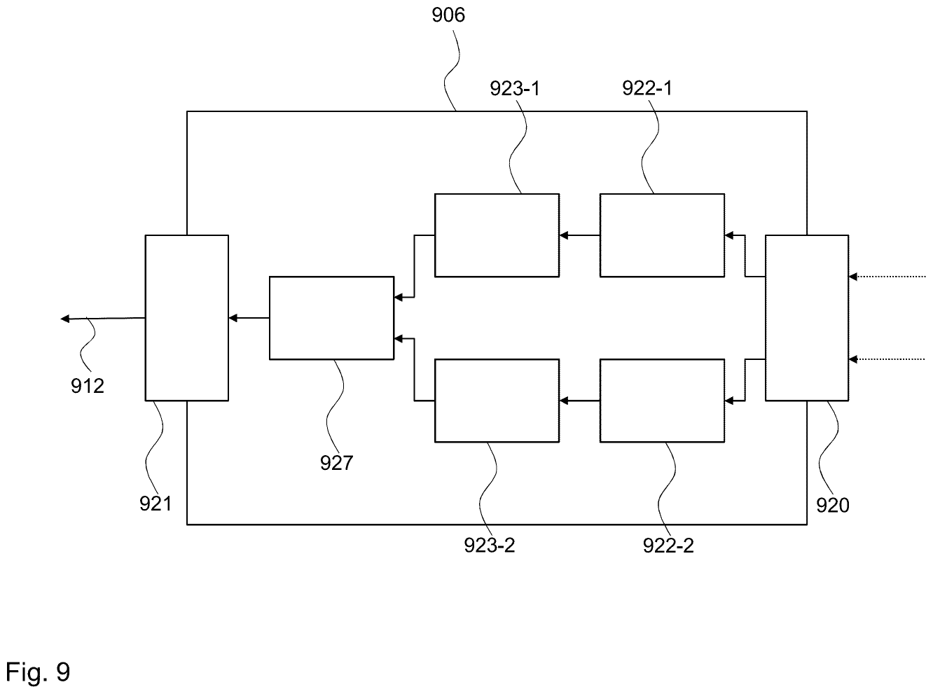

FIG. 9 shows a property measurement unit 906. It is understood that the explanations regarding other embodiments of the property measurement unit described herein apply mutatis mutandis to the property measurement unit 906.

The property measurement unit 906 comprises an input interface 920 which receives the second part of the test signal and the reflected optical signal separately.

The input interface 920 is coupled to a first photodetector 922-1 and a second photodetector 922-2.

The first photodetector 922-1 captures the second part of the optical test signal and outputs a first electrical signal to a first analog-to-digital converter 923-1. The second photodetector 922-2 captures the reflected optical signal and outputs a second electrical signal to a second analog-to-digital converter 923-2.

The first analog-to-digital converter 923-1 converts the first electrical signal into a first digital signal. The second analog-to-digital converter 923-2 converts the second electrical signal into a second digital signal. A combiner 927 combines the first digital signal with the second digital signal and outputs them via the data interface 921 as the physical property 912.

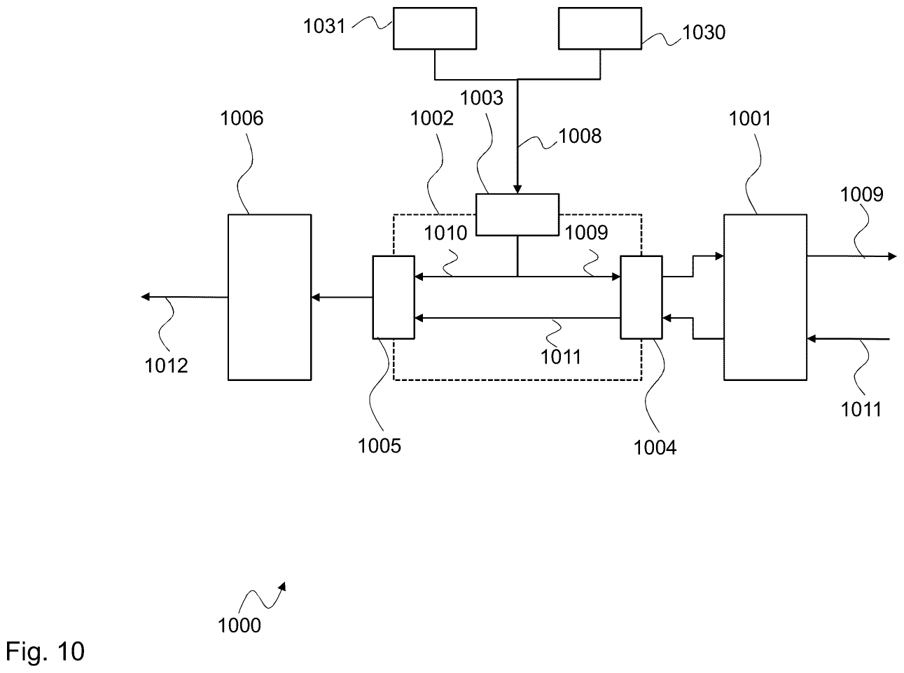

FIG. 10 shows a conductor correction module 1000. The conductor correction module 1000 is based on the conductor correction module 1000. Consequently, the conductor correction module 1000 comprises: a bidirectional optical interface 1001, an optical splitter 1002, and a property measurement unit 1006. The optical splitter 1002 comprises an input interface 1003, a bidirectional test signal interface 1004, and an output interface 1005. The bidirectional optical interface 1001 can be coupled to at least one optical conductor of a conductor. The bidirectional test signal interface 1004 of the optical splitter 1002 is coupled to the bidirectional optical interface 1001; the output interface 1005 of the optical splitter 1002 is coupled to the property measurement unit 1006. It is understood that the explanations regarding other embodiments of the conductor correction module described herein apply mutatis mutandis to the conductor correction module 1000.

The conductor correction module 1000 further comprises an optical signal source 1030 and an optical input interface 1031. It is understood that the conductor correction module 1000 can also comprise only the optical signal source 1030 or the optical input interface 1031.

The optical signal source 1030 is coupled to the input interface 1003 of the optical splitter 1002 and outputs the optical test signal 1008 to the optical splitter 1002.

The optical input interface 1031 is coupled to the input interface 1003 of the optical splitter 1002 and receives the optical test signal 1008 to transmit it to the optical splitter 1002.

The optical test signal 1008 can be, for example, a periodically modulated signal, an amplitude-modulated signal, a phase-modulated signal, a frequency-modulated signal, a chirp-modulated signal, or a pulse-modulated signal.

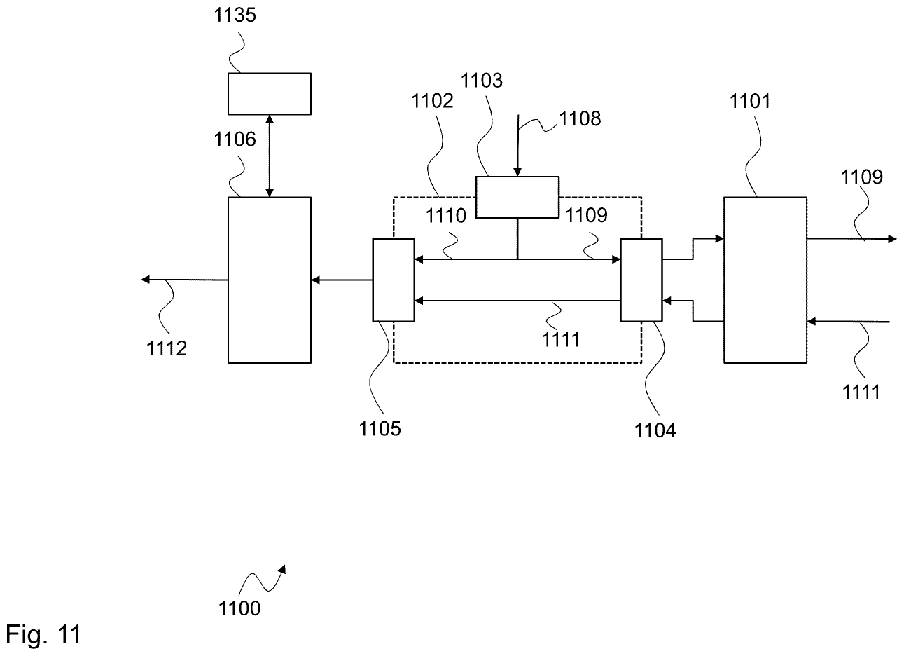

FIG. 11 shows a conductor correction module 1100. The conductor correction module 1100 is based on the conductor correction module 1100. Consequently, the conductor correction module 1100 comprises: a bidirectional optical interface 1101, an optical splitter 1102, and a property measurement unit 1106. The optical splitter 1102 comprises an input interface 1103, a bidirectional test signal interface 1104, and an output interface 1105. The bidirectional optical interface 1101 can be coupled to at least one optical conductor of a conductor. The bidirectional test signal interface 1104 of the optical splitter 1102 is coupled to the bidirectional optical interface 1101; the output interface 1105 of the optical splitter 1102 is coupled to the property measurement unit 1106. It is understood that the explanations regarding other embodiments of the conductor correction module described herein apply mutatis mutandis to the conductor correction module 1100.

The conductor correction module 1100 further comprises a memory 1135. The memory 1135 can store the length of the conductor 1341 in a reference state. This length can be captured, for example, during production of the conductor and stored in the memory 1135 together with a serial number of the conductor.

Alternatively, the length can be determined metrologically, for example. The length of the conductor can also be read out wirelessly, e.g., via an RFID interface, or contact-based from a memory in the conductor. For this purpose, the conductor correction module 1100 can comprise, for example, a corresponding interface. The length of the conductor can also be transmitted to the conductor correction module 1100 by a corresponding measurement application device.

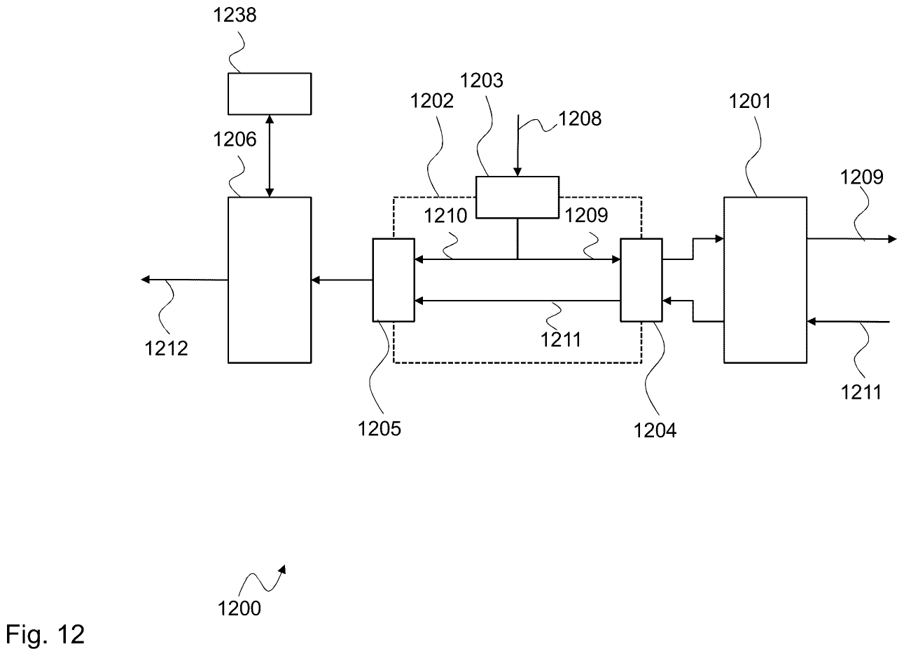

FIG. 12 shows a conductor correction module 1200. The conductor correction module 1200 is based on the conductor correction module 1200. Consequently, the conductor correction module 1200 comprises: a bidirectional optical interface 1201, an optical splitter 1202, and a property measurement unit 1206. The optical splitter 1202 comprises an input interface 1203, a bidirectional test signal interface 1204, and an output interface 1205. The bidirectional optical interface 1201 can be coupled to at least one optical conductor of a conductor. The bidirectional test signal interface 1204 of the optical splitter 1202 is coupled to the bidirectional optical interface 1201; the output interface 1205 of the optical splitter 1202 is coupled to the property measurement unit 1206. It is understood that the explanations regarding other embodiments of the conductor correction module described herein apply mutatis mutandis to the conductor correction module 1200.

The conductor correction module 1200 further comprises a timing unit 1238. The timing unit 1238 is coupled to the property measurement unit 1206 and is configured to output a timing signal.

The property measurement unit 1206 can determine an absolute propagation time of the first part 1209 of the optical test signal 1208 in the conductor based on the timing signal. Based on the absolute propagation time, the absolute length of the conductor can be determined, for example.

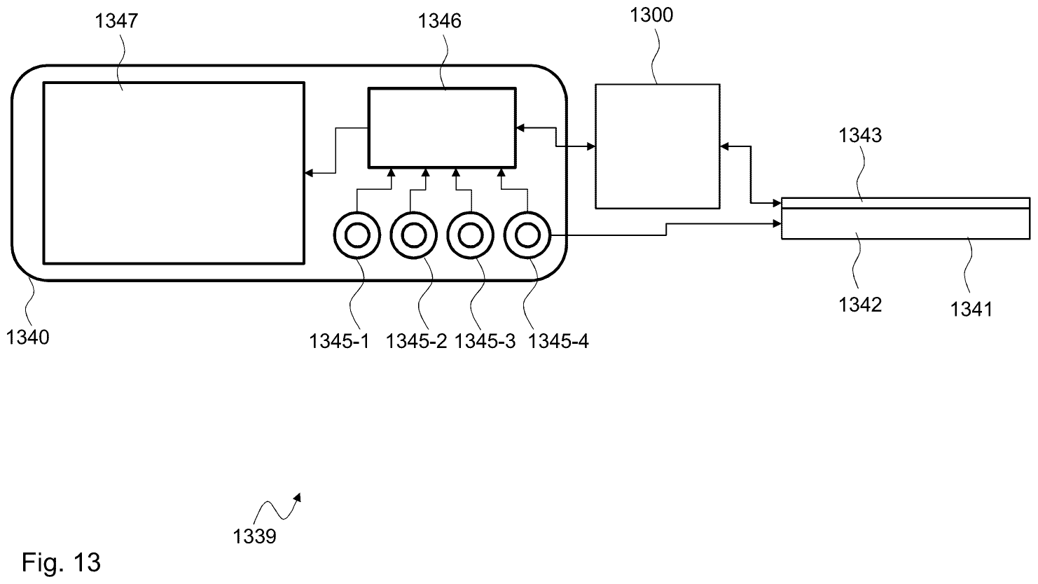

FIG. 13 shows a block diagram of a measurement application system 1339. The measurement application system 1339 comprises a measurement application device, exemplified as an oscilloscope 1340, which has four measurement inputs 1345-1, 1345-2, 1345-3, 1345-4. One of the measurement inputs 1345-1, 1345-2, 1345-3, 1345-4 is electrically coupled to an RF conductor 1342 of a conductor 1341. Furthermore, a conductor correction module 1300 is coupled to an optical conductor 1343 of the conductor 1341 and to a processor 1346 of the oscilloscope 1340.

It is understood that the conductor correction module 1300 can comprise an RF signal path, and the corresponding measurement input 1345-1, 1345-2, 1345-3, 1345-4 can be coupled to the RF conductor 1342 via the conductor correction module 1300.

In embodiments, the conductor correction module 1300 can also be arranged in the measurement application device 1340 or in the conductor 1341.

Since the devices and methods described in detail above are exemplary embodiments, they can be modified by the skilled person in a wide range in the usual manner without departing from the scope of the disclosure. In particular, the mechanical arrangements and the size ratios of the individual elements to one another are merely exemplary.

### LIST OF REFERENCE SIGNS

100, 200, 300, 400, 500, 1000 Conductor correction module
1100, 1200, 1300 Conductor correction module
101, 201, 301, 401, 501, 1001 Bidirectional optical interface
102, 202, 302, 402, 502, 1002 Optical splitter
1102, 1202 Optical splitter
103, 203, 303, 403, 503, 1003 Input interface
1103, 1203 Input interface
104, 204, 304, 404, 504, 1004 Bidirectional test signal interface
1104, 1204 Bidirectional test signal interface
105, 205, 305, 405, 505, 1005 Output interface
1105, 1205 Output interface
106, 206, 306, 406, 506, 606, 706, 806 Property measurement unit
906, 1006, 1106, 1206 Property measurement unit
108, 208, 308, 408, 508, 1008 Optical test signal
1108, 1208 Optical test signal
109, 209, 309, 409, 509, 1009 First part
1109, 1209 First part
110, 210, 310, 410, 510, 1010 Second part
1110, 1210 Second part
111, 211, 311, 411, 511, 1011 Reflected optical signal
1111, 1211 Reflected optical signal
112, 212, 312, 412, 512, 612, 712, 812 Physical property
912, 1012, 1112, 1212 Physical property
113 RF signal path
215, 315-1, 315-2 Signal port
416, 516-1, 516-2 Signal port
620, 720, 820, 920 Input interface
621, 721, 821, 921 Digital data interface
622, 722-1, 722-2, 822, 922-1, 922-2 Photodetector
623, 723, 823, 923-1, 923-2 Analog-to-digital converter
725 Electrical combiner
826 Optical combiner
927 Digital combiner
1030 Optical signal source
1031 Optical input interface
1135 Memory
1238 Timing unit
1339 Measurement application system
1340 Measurement application device
1341 Conductor
1342 RF conductor
1343 Optical conductor
1345-1, 1345-2, 1345-3, 1345-4 Measurement input
1346 Processor
1347 Display

1. A conductor correction module for continuous or discrete-time capture of properties of a conductor for electrical signal transmission, wherein the conductor correction module comprises:
a bidirectional optical interface couplable to at least one optical conductor of the conductor;
an optical splitter comprising an input interface, a bidirectional test signal interface, and an output interface; and
a property measurement unit coupled to the output interface of the optical splitter,
wherein the bidirectional test signal interface of the optical splitter is coupled to the bidirectional optical interface,
wherein the optical splitter is configured to receive an optical test signal via the input interface and output a first part of the optical test signal via the bidirectional test signal interface and a second part of the optical test signal via the output interface,
wherein the bidirectional optical interface is configured to forward the first part of the optical test signal into the optical conductor, and receive a reflected optical signal from the optical conductor and forward it to the bidirectional test signal interface,
wherein the optical splitter is further configured to output the received reflected optical signal via the output interface, and
wherein the property measurement unit is configured to determine at least one physical property of the conductor based on the second part of the optical test signal and the received reflected optical signal.

2. The conductor correction module according to claim 1, wherein the bidirectional test signal interface of the optical splitter comprises a single signal port configured to emit the first part of the optical test signal and receive the reflected optical signal.

3. The conductor correction module according to claim 1, wherein the bidirectional test signal interface of the optical splitter comprises a first signal port and a second signal port, wherein the first signal port is configured to emit the first part of the optical test signal, and the second signal port is configured to receive the reflected optical signal.

4. The conductor correction module according to claim 1, wherein the output interface of the optical splitter comprises a single signal port configured to output the second part of the optical test signal and output the reflected optical signal.

5. The conductor correction module according to claim 1, wherein the output interface of the optical splitter comprises a first signal port and a second signal port, wherein the first signal port is configured to output the second part of the optical test signal, and the second signal port is configured to output the reflected optical signal.

6. The conductor correction module according to claim 1, wherein the property measurement unit comprises a digital data interface, and is configured to output determined physical properties via the digital data interface.

7. The conductor correction module according to claim 1, wherein the property measurement unit is configured to perform at least one of:
determine a phase difference between the second part of the optical test signal and the reflected optical signal;
determine a time difference between the second part of the optical test signal and the reflected optical signal;
determine correlation information between the second part of the optical test signal and the reflected optical signal; and
determine amplitude information for the second part of the optical test signal and the reflected optical signal.

8. The conductor correction module according to claim 1, wherein the property measurement unit comprises at least one photodetector and at least one analog-to-digital converter coupled to the at least one photodetector.

9. The conductor correction module according to claim 1, wherein the property measurement unit comprises:
a first photodetector configured to capture the second part of the optical test signal and output a first electrical signal;
a second photodetector configured to capture the reflected optical signal and output a second electrical signal;
a combiner coupled to the first photodetector and the second photodetector, and configured to combine the first electrical signal with the second electrical signal; and
an analog-to-digital converter coupled to the combiner and configured to convert the combined electrical signal into a digital signal and output the digital signal.

10. The conductor correction module according to claim 1, wherein the property measurement unit comprises:
an optical combiner configured to combine the second part of the optical test signal with the reflected optical signal;
a photodetector coupled to the optical combiner and configured to capture the combined optical signal and output a corresponding electrical signal; and
an analog-to-digital converter coupled to the photodetector and configured to convert the electrical signal into a digital signal and output the digital signal.

11. The conductor correction module according to claim 1, wherein the optical splitter is configured to output the second part of the optical test signal and the reflected optical signal as a combined optical signal to the property measurement unit, wherein the property measurement unit comprises:
a photodetector configured to capture the combined optical signal and output a corresponding electrical signal; and
an analog-to-digital converter coupled to the photodetector and configured to convert the electrical signal into a digital signal and output the digital signal.

12. The conductor correction module according to claim 1, wherein the property measurement unit comprises:
a first photodetector configured to capture the second part of the optical test signal and output a first electrical signal;
a second photodetector configured to capture the reflected optical signal and output a second electrical signal;
a first analog-to-digital converter coupled to the first photodetector and configured to convert the first electrical signal into a first digital signal;
a second analog-to-digital converter coupled to the second photodetector and configured to convert the second electrical signal into a second digital signal; and
a combiner coupled to the first analog-to-digital converter and the second analog-to-digital converter, and configured to combine the first digital signal with the second digital signal and output the combined digital signal.

13. The conductor correction module according to claim 1, further comprising an optical signal source coupled to the input interface of the optical splitter and configured to generate the optical test signal and transmit the optical test signal to the optical splitter.

14. The conductor correction module according to claim 1, further comprising an optical input interface coupled to the input interface of the optical splitter and configured to receive the optical test signal and transmit the optical test signal to the optical splitter.

15. The conductor correction module according to claim 1, wherein the optical test signal comprises at least one signal from the following optical signals:
a periodically modulated signal;
an amplitude-modulated signal;
a phase-modulated signal;
a frequency-modulated signal;
a chirp-modulated signal; or
a pulse-modulated signal.

16. The conductor correction module according to claim 1, wherein the property measurement unit is configured to determine a change in an absolute length of the conductor based on the second part of the optical test signal and the received reflected optical signal.

17. The conductor correction module according to claim 16, further comprising a memory configured to store the absolute length of the conductor in a reference state.

18. The conductor correction module according to claim 16, further comprising a timing unit coupled to the property measurement unit and configured to output a timing signal, wherein the property measurement unit is configured to determine an absolute propagation time of the first part of the optical test signal in the conductor based on the timing signal.

19. A measurement application system comprising:
a conductor comprising an electrical conductor and an optical conductor;
conductor correction module comprising:
a bidirectional optical interface coupled to the optical conductor of the conductor;
an optical splitter comprising an input interface, a bidirectional test signal interface, and an output interface; and
a property measurement unit coupled to the output interface of the optical splitter,
wherein the bidirectional test signal interface of the optical splitter is coupled to the bidirectional optical interface,
wherein the optical splitter is configured to receive an optical test signal via the input interface and output a first part of the optical test signal via the bidirectional test signal interface and a second part of the optical test signal via the output interface,
wherein the bidirectional optical interface is configured to forward the first part of the optical test signal into the optical conductor, and receive a reflected optical signal from the optical conductor and forward it to the bidirectional test signal interface,
wherein the optical splitter is further configured to output the received reflected optical signal via the output interface, and
wherein the property measurement unit is configured to determine at least one physical property of the conductor based on the second part of the optical test signal and the received reflected optical signal; and
a measurement application device coupled directly or indirectly via the conductor correction module to the electrical conductor of the conductor,
wherein the measurement application device is configured to adapt a signal processing based on at least one physical property of the conductor determined by the conductor correction module.

20. The measurement application system according to claim 19, wherein one of:
the conductor correction module is arranged in the measurement application device,
the conductor correction module is arranged externally to the measurement application device and the conductor, between the measurement application device and the conductor, or
the conductor correction module is arranged in the conductor.
